(19) United States
(12) Patent Application Publication
(10) Pub. No.: US 2015/0244401 A1
(43) Pub. Date: Aug. 27, 2015

(54) TRANSMITTING DEVICE AND ASSOCIATED TRANSMITTING METHOD FOR POWER EFFICIENCY ENHANCEMENT

(71) Applicant: Mediatek Inc., Hsin-Chu (TW)

(72) Inventors: Yuan-Hung Chung, Hsinchu County (TW); Meng-Hsiung Hung, Hsinchu City (TW); Chun-Wei Lin, Pingtung County (TW); Wei-Kai Hong, New Taipei City (TW); Keng Leong Fong, Sunnyvale, CA (US); George Chien, Saratoga, CA (US); Ming-Yeh Hsu, Taoyuan City (TW)

(21) Appl. No.: 14/617,938

(22) Filed: Feb. 10, 2015

Related U.S. Application Data
(60) Provisional application No. 61/942,788, filed on Feb. 21, 2014.

(51) Int. Cl. H04B 1/02; H04W 4/00; H03F 1/02; H03F 3/189; H03F 3/20

(52) U.S. Cl. CPC H04B 1/02; H03F 3/189; H03F 3/20; H03F 1/02; H04W 4/008; H03F 2200/451; H03F 2200/387; H04W 84/12

(57) ABSTRACT

A transmitting device includes a transmitting chain, a configurable power amplifier device and an impedance tuning circuit. The transmitting chain is arranged to generate a radio frequency signal. The configurable power amplifier device is arranged to support at least a first power amplifier configuration and a second power amplifier configuration, wherein the configurable power amplifier device employs the first power amplifier configuration to receive and amplify the radio frequency signal when the transmitting device is operated in a first operation mode, and employs the second power amplifier configuration to receive and amplify the radio frequency signal when the transmitting device is operated in a second operation mode. The impedance tuning circuit is arranged to adjust an output impedance of the configurable power amplifier device employing the second power amplifier configuration when the transmitting device is operated in the second operation mode.

### CROSS REFERENCE TO RELATED APPLICATIONS

This application claims the benefit of U.S. provisional application No. 61/942,788, filed on Feb. 21, 2014 and incorporated herein by reference.

### BACKGROUND

The disclosed embodiments of the present invention relate to wireless communications, and more particularly, to a transmitting device and an associated transmitting method for power efficiency enhancement.

The wireless fidelity (WiFi) technique is widely applied in daily life. WiFi applications can be seen in most portable devices, such as smart phones, tablets, wireless storage devices, devices for transmitting video data such as Miracast devices, and wearable electronic devices such as smart glasses devices. Based on current WiFi designs, however, it is difficult to realize power amplifiers with low power consumption, which means that the battery life of the portable device cannot be extended.

An efficient power amplifier design is the key to extending battery life to achieve a better user experience. Low power BT (Bluetooth)/BLE (Bluetooth 4.0) techniques are commonly applied in wearable devices, but the power efficiency of the conventional transmitting devices is still not good enough.

Therefore, there is a need for a novel method and an associated mechanism to improve the overall power efficiency of a transmitting device.

### SUMMARY

An objective of the present invention is to provide a transmitting device and an associated transmitting method for power efficiency enhancement, in order to solve the aforementioned problem.

An embodiment of the present invention provides a transmitting device, which includes a transmitting chain, a configurable power amplifier device and an impedance tuning circuit. The transmitting chain is arranged to generate a radio frequency (RF) signal. The configurable power amplifier device is arranged to support at least a first power amplifier configuration and a second power amplifier configuration, wherein the configurable power amplifier device employs the first power amplifier configuration to receive and amplify the RF signal when the transmitting device is operated in a first operation mode, and employs the second power amplifier configuration to receive and amplify the RF signal when the transmitting device is operated in a second operation mode. The impedance tuning circuit is arranged to adjust an output impedance of the configurable power amplifier device employing the second power amplifier configuration when the transmitting device is operated in the second operation mode.

Another embodiment of the present invention provides a transmitting method, which is applied to a transmitting device. The transmitting method includes: generating a radio frequency (RF) signal; using a configurable power amplifier device to support at least a first power amplifier configuration and a second power amplifier configuration, wherein the configurable power amplifier device employs the first power amplifier configuration to receive and amplify the RF signal when the transmitting device is operated in a first operation mode, and employs the second power amplifier configuration to receive and amplify the RF signal when the transmitting device is operated in a second operation mode; and adjusting an output impedance of the configurable power amplifier device employing the second power amplifier configuration when the transmitting device is operated in the second operation mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a transmitting device according to an embodiment of the present invention.

FIG. 2 is a diagram illustrating a transmitting device according to another embodiment of the present invention.

FIGS. 3-5 are diagrams illustrating configurations of the power amplifiers and in the transmitting device shown in FIG. 2 according to embodiments of the present invention.

FIG. 6 is a flowchart illustrating a transmitting method according to an embodiment of the present invention.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should not be interpreted as a close-ended term such as “consist of”. Also, the term “couple” is intended to mean either an indirect or direct electrical connection. Accordingly, if one device is coupled to another device, that connection may be through a direct electrical connection, or through an indirect electrical connection via other devices and connections.

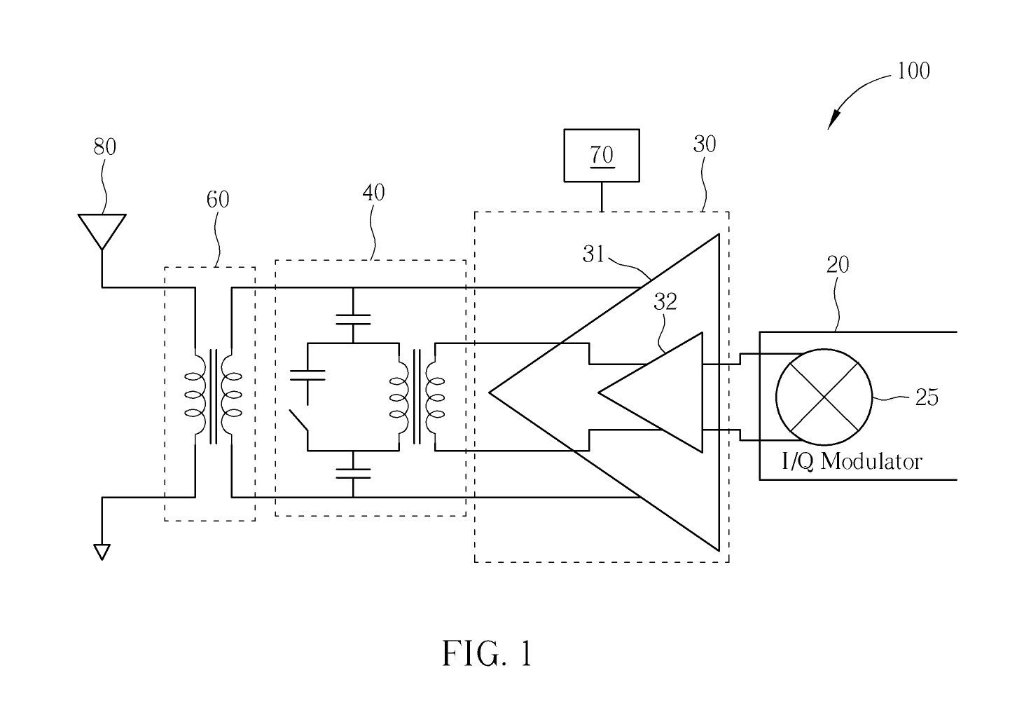

Please refer to FIG. 1, which is a diagram illustrating a transmitting device 100 according to an embodiment of the present invention. By way of example, the transmitting device 100 may be implemented in a portable device, such as a mobile phone, a tablet, or a wearable device. The portable device is equipped with wireless communications capability due to the transmitting device 100. The transmitting device 100 includes a transmitting chain 20, a configurable power amplifier (PA) device 30, an impedance tuning circuit 40, a balun 60, a controller 70, and an antenna 80. The transmitting chain 20 is arranged to generate radio frequency (RF) signals, and may include at least an in-phase/quadrature (I/Q) modulator 25 which is coupled to the configurable power amplifier device 30. Note that the transmitting chain 20 may include more circuit elements for generating the RF signals to be transmitted over the air. For clarity and simplicity, FIG. 1 only shows a final stage (e.g., I/Q modulator 25) of the transmitting chain 20.

The configurable power amplifier device 30 is arranged to support at least a first power amplifier configuration and a second power amplifier configuration, each arranged for delivering different levels of signals. Specifically, when the transmitting device is operated in a first operation mode, the configurable power amplifier device 30 employs the first power amplifier configuration to receive and amplify the RF signal, and when the transmitting device is operated in a second operation mode, the configurable power amplifier device 30 employs the second power amplifier configuration to receive and amplify the RF signal, wherein the first power amplifier configuration is arranged to deliver signals having a higher level, and the second power amplifier configuration is arranged to deliver signals having a lower level.

More specifically, when the RF signal complies with a first communications standard, the transmitting device 100 is operated in the first operation mode; and when the RF signal complies with a second communications standard, the transmitting device 100 is operated in the second operation mode. For example, the first communications standard may be a WiFi protocol, and the second communications standard may be a Bluetooth (BT) protocol. Please note that the first power amplifier configuration and the second power amplifier configuration have different power consumptions, and the power consumption of the first power amplifier configuration is higher than the power consumption of the second power amplifier configuration.

The configurable power amplifier device 30 may employ two power amplifiers 31 and 32 arranged to be operated in the aforementioned two operation modes, respectively. This is merely for illustrative purposes. In some modifications of this embodiment, the configurable power amplifier device 30 may include more amplifiers operated in more modes corresponding to different RF signal levels and having different respective power consumptions.

The transmitting device 100 may enable one of the two power amplifiers 31 and 32 according to the power consumption. For example, when the configurable power amplifier device 30 employs the first power amplifier configuration, the first power amplifier 31 is enabled, and the second power amplifier 32 is disabled; and when the configurable power amplifier device 30 employs the second power amplifier configuration, the second power amplifier 32 is enabled, and the first power amplifier 31 is disabled.

When the transmitting device 100 is operated in the second operation mode, the configurable power amplifier device 30 will employ the second power amplifier configuration. At this time, the impedance tuning circuit 40 is arranged to adjust the output impedance of the configurable power amplifier device 30 employing the second power amplifier configuration. The impedance tuning circuit 40 may be an impedance transformation network (ITN), and more particularly, a tunable impedance transformation network as illustrated in FIG. 1. The impedance tuning circuit 40 is designed so that the separated power amplifiers can individually achieve the best power efficiency. Since the power consumption of the first power amplifier configuration is higher than the power consumption of the second power amplifier configuration, the adjusted output impedance generated by the impedance tuning circuit 40 when the transmitting device 100 is operated in the second operation mode is configured to be larger than the output impedance of the configurable power amplifier device 30 employing the first power amplifier configuration when the transmitting device 100 is operated in the first operation mode.

The controller 70 may be designed/programmed based on the aforementioned power amplifier design. When the configurable power amplifier device 30 employs the first power amplifier configuration, the controller 70 may enable the first power amplifier 31 and disable the second power amplifier 32; and when the configurable power amplifier device 30 employs the second power amplifier configuration, the controller 70 may enable the second power amplifier 32 and disable the first power amplifier 31. Note that the transmitting device 100 may further include a switch coupled between the controller 70 and the first power amplifier 31, and another switch coupled between the controller 70 and the second power amplifier 32. In this way, the first/second operation mode may be employed by turning on one switch and turning off the other switch. This is merely for illustrative purposes, rather than a limitation of the present invention.

The balun 60 is coupled between the antenna 80 and the impedance tuning circuit 40, and is arranged to convert RF signals (which are differential signals) received from the impedance tuning circuit 40 into single-ended RF signals that are radiated through the antenna 80. Since one skilled in the art should readily understand the function and operation of the balun 60, a detailed descriptions is omitted here for brevity.

In this embodiment, the transmitting device 100 may refer to the type of RF signal inputted from the transmitting chain 20, in order to select a proper operation mode to reach high transmission efficiency. The configurable power amplifier architecture is capable of saving current in various operation modes, such as BT, WiFi, Miracast and Infrastructure modes. Further, the impedance tuning circuit 40 (e.g. a tunable ITN) is utilized to provide optimized impedance for the separated power amplifiers 31 and 32 to achieve the best power efficiency.

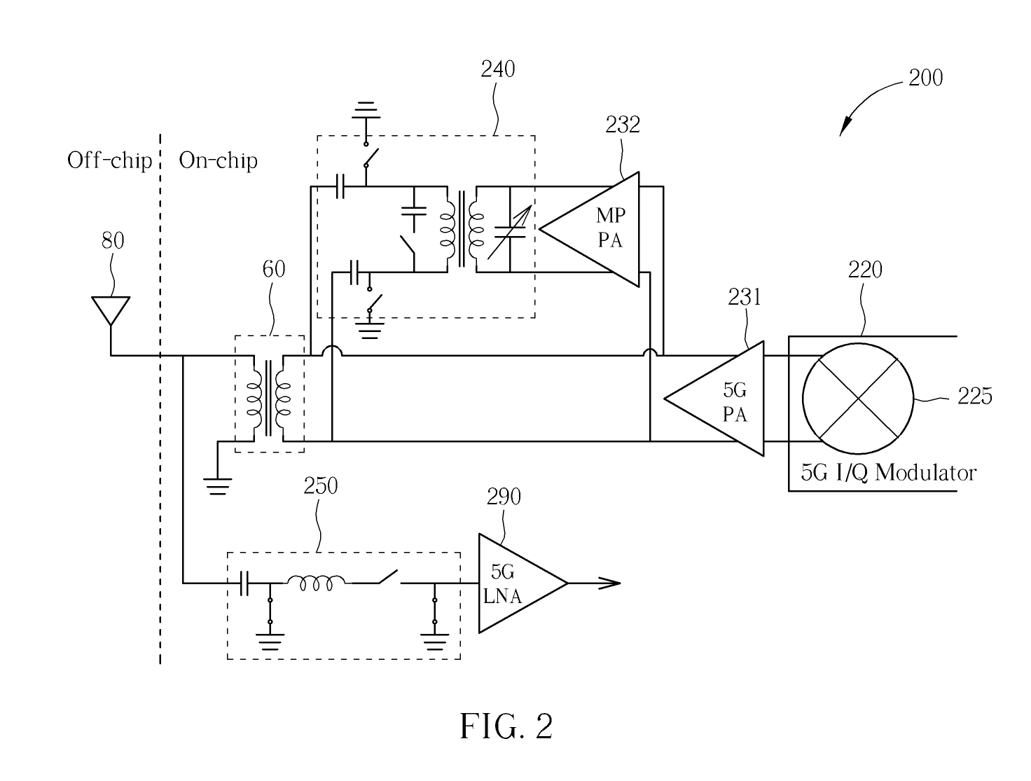

Please refer to FIG. 2, which is a diagram illustrating a transmitting device 200 according to another embodiment of the present invention. By way of example, the transmitting device 200 may be implemented in a portable device, such as a mobile phone, a tablet, or a wearable device. The portable device has wireless communications capability due to the transmitting device 200. Note that, in this embodiment, the elements on the right side of the vertical dotted line are on-chip elements, and the elements on the left side of the vertical dotted line are off-chip elements. The transmitting device 200 includes a transmitting chain 220, power amplifiers 231 and 232, an impedance tuning circuit 240, a balun 60, and an antenna 80. The difference between this embodiment shown in FIG. 2 and the previous embodiment shown in FIG. 1 is that the transmitting device 200 further includes a matching network 250 and a low noise amplifier (LNA) 290 as the receiving chain. The transmitting chain 220 is arranged to generate RF signals, and includes at least an I/Q modulator 225 which is coupled to a configurable power amplifier device having the power amplifiers 231 and 232. In this embodiment, the power amplifier 231 may be a 5 GHz full-power amplifier, the power amplifier 232 may be a 5 GHz middle-power power amplifier, the I/Q modulator 225 may be a 5 GHz I/Q modulator 225, and the LNA 290 may be a 5 GHz LNA.

The LNA 290 is an electronic amplifier arranged to amplify very weak signals (for example, those captured by an antenna). The effect of noise from the balun 60 and the impedance tuning circuit 240 of the transmitting device 200 may be reduced by the gain of the matching network 250. Further, the matching network 250 is arranged to perform input impedance matching for the LNA 290, and may include some passive elements such a capacitor, an inductor and a switch. Note the elements depicted in the impedance tuning circuit 240 are merely for illustrative purposes, and not meant to be limitations to the present invention.

The balun 60 may arranged to be on-chip or off-chip, i.e. the LNA 290 may be coupled to the front end or the back end of the balun 60. For example, when coupled to back end (differential side) of the balun 60, the matching network of LNA 290 can be implemented with a tunable ITN (e.g. the impedance tuning circuit 40 shown in FIG. 1). Further, the tunable ITN can be used to assist to receive chain matching.

Similarly, the transmitting device 200 may refer to the type of RF signal inputted from the transmitting chain 220, in order to select a proper operation mode to reach high transmission efficiency. The configurable power amplifier architecture of the transmitting device 200 is capable of saving the current in various operation modes, such as BT, WiFi, Miracast and Infrastructure modes. Further, the impedance tuning circuit (e.g. a tunable ITN) 240 is utilized to provide optimized impedance for the separated power amplifiers 231 and 232 to achieve the best power efficiency.

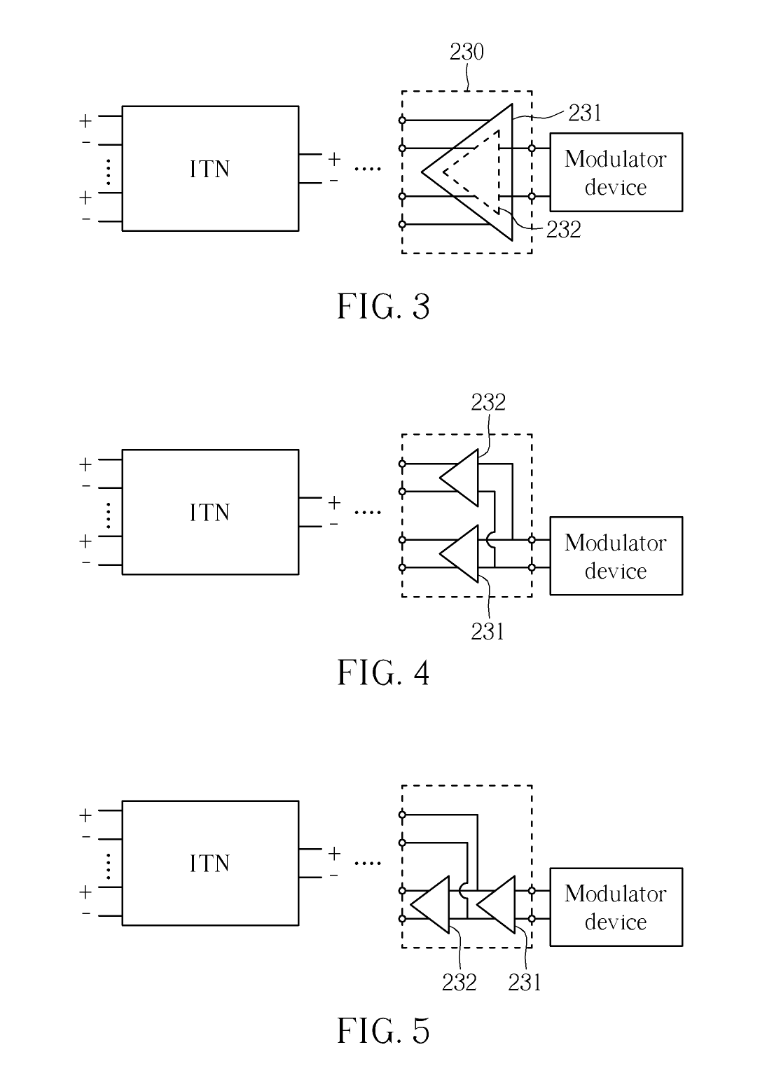

Please note that the power amplifiers 231 and 232 may be arranged in a cascade manner, parallel connected, or embedded in an amplifier circuit. Refer to FIGS. 3-5, which are diagrams illustrating some possible configurations of the power amplifiers 231 and 232 in the transmitting device 200 shown in FIG. 2 according to embodiments of the present invention. As shown in FIG. 3, the power amplifiers 231 and 232 may be both embedded in an amplifier circuit 230. Further, a parallel connection and a cascade connection are shown in FIGS. 4-5, respectively. For brevity, in FIGS. 3-5, the right part of the power amplifiers 231 and 232 is simplified as a modulator device, the left part of the power amplifiers 231 and 232 is simplified as an impedance transformation network (ITN), and some regions previously depicted in FIG. 2 are omitted.

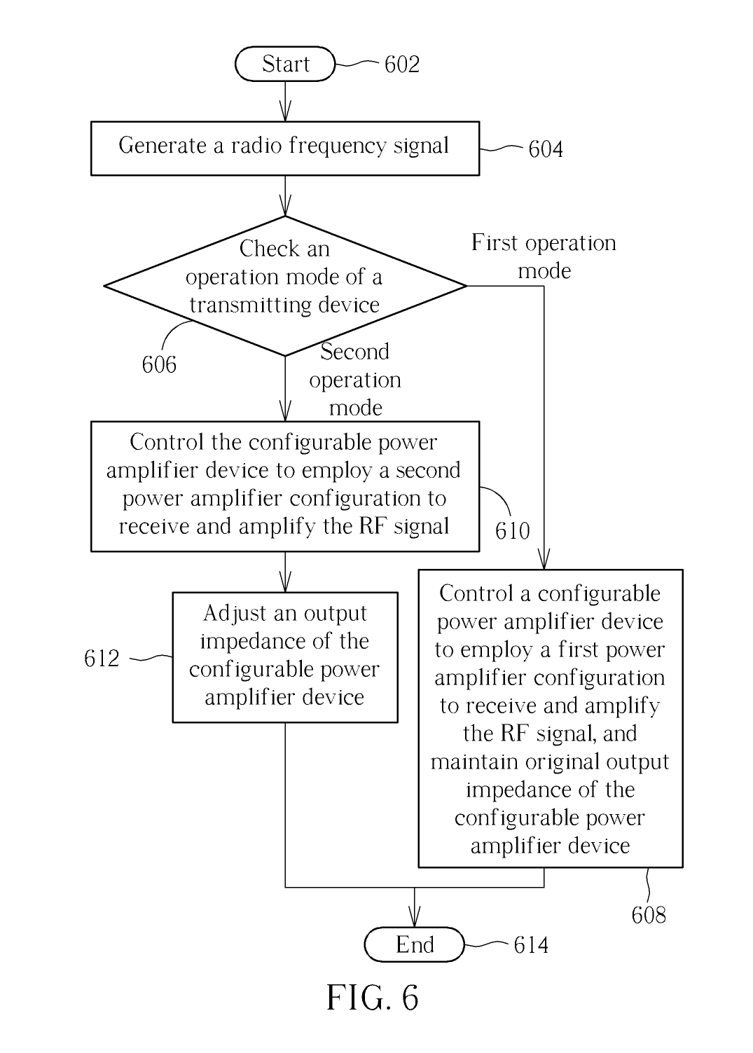

Please refer to FIG. 6, which is a flowchart illustrating a transmitting method according to an embodiment of the present invention. If the result is substantially the same, the steps are not required to be executed in the exact order shown in FIG. 6. The method shown in FIG. 6 may be employed by either of the transmitting devices 100 and 200, and can be briefly summarized as follows.

Step 602: Start.

Step 604: Generate a radio frequency signal.

Step 606: Check an operation mode of a transmitting device. If the transmitting device is operated in a first operation mode, go to step 608. If the transmitting device is operated in a second operation mode, go to step 610.

Step 608: Control a configurable power amplifier device to employ a first power amplifier configuration to receive and amplify the RF signal, and maintain original output impedance of the configurable power amplifier device. Go to step 614.

Step 610: Control the configurable power amplifier device to employ a second power amplifier configuration to receive and amplify the RF signal.

Step 612: Adjust an output impedance of the configurable power amplifier device.

Step 614: End.

The above transmitting method illustrates operations of the transmitting devices 100 and 200. As one skilled in the art can understand details of each step after reading the corresponding descriptions in the above paragraphs, further description is omitted here for brevity.

To summarize, the configurable power amplifier architecture of the present invention may employ a proper amplifier and may further adjust the tunable ITN circuit based on the inputted RF signal, which improves the overall power efficiency of the transmitting device without sacrificing the performance. Further, although the two power amplifiers of the configurable power amplifier device shown in the above embodiments are arranged in a parallel connection fashion, the present invention is not limited thereto. In some modifications of the above embodiments, the two power amplifiers may be arranged in a cascade manner based on the design requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transmitting device, comprising:
a transmitting chain, arranged to generate a radio frequency (RF) signal;
a configurable power amplifier device, arranged to support at least a first power amplifier configuration and a second power amplifier configuration, wherein the configurable power amplifier device employs the first power amplifier configuration to receive and amplify the RF signal when the transmitting device is operated in a first operation mode, and employs the second power amplifier configuration to receive and amplify the RF signal when the transmitting device is operated in a second operation mode; and
an impedance tuning circuit, arranged to adjust an output impedance of the configurable power amplifier device employing the second power amplifier configuration when the transmitting device is operated in the second operation mode.

2. The transmitting device of claim 1, wherein the configurable power amplifier device comprises:
a first power amplifier; and
a second power amplifier;
wherein when the configurable power amplifier device employs the first power amplifier configuration, the first power amplifier is used to receive and amplify the RF signal, and when the configurable power amplifier device employs the second power amplifier configuration, the second power amplifier is used to receive and amplify the RF signal.

3. The transmitting device of claim 2, further comprising:
a controller, arranged to enable the first power amplifier and disable the second power amplifier when the transmitting device is operated in the first operation mode, and enable the second power amplifier and disable the first power amplifier when the transmitting device is operated in the second operation mode.

4. The transmitting device of claim 2, wherein the first amplifier and the second amplifier are coupled in cascade.

5. The transmitting device of claim 2, wherein the first amplifier and the second amplifier are parallel coupled.

6. The transmitting device of claim 2, wherein the first amplifier and the second amplifier are embedded in an amplifier circuit.

7. The transmitting device of claim 1, wherein the impedance tuning circuit is an impedance transformation network (ITN).

8. The transmitting device of claim 7, wherein the ITN is tunable.

9. The transmitting device of claim 1, wherein the first power amplifier configuration and the second power amplifier configuration have different power consumptions.

10. The transmitting device of claim 1, wherein a power consumption of the first power amplifier configuration is higher than a power consumption of the second power amplifier configuration.

11. The transmitting device of claim 10, wherein the adjusted output impedance generated by the impedance tuning circuit when the transmitting device is operated in the second operation mode is larger than an output impedance of the configurable power amplifier device employing the first power amplifier configuration when the transmitting device is operated in the first operation mode.

12. The transmitting device of claim 1, wherein when the RF signal complies with a first communications standard, the transmitting device is operated in the first operation mode; and when the RF signal complies with a second communications standard, the transmitting device is operated in the second operation mode.

13. The transmitting device of claim 12, wherein the first communications standard is a Wireless Fidelity (WiFi) protocol, and the second communications standard is a Bluetooth (BT) protocol.

14. A transmitting method, comprising:
generating a radio frequency (RF) signal;
using a configurable power amplifier device to support at least a first power amplifier configuration and a second power amplifier configuration, wherein the configurable power amplifier device employs the first power amplifier configuration to receive and amplify the RF signal when a transmitting device is operated in a first operation mode, and employs the second power amplifier configuration to receive and amplify the RF signal when the transmitting device is operated in a second operation mode; and
adjusting an output impedance of the configurable power amplifier device employing the second power amplifier configuration when the transmitting device is operated in the second operation mode.

15. The transmitting method of claim 14, further comprising:
receiving and amplifying the RF signal with a first power amplifier of the configurable power amplifier device when the configurable power amplifier device employs the first power amplifier configuration; and
receiving and amplifying the RF signal with a second power amplifier of the configurable power amplifier device when the configurable power amplifier device employs the second power amplifier configuration.

16. The transmitting method of claim 15, further comprising:
enabling the first power amplifier and disabling the second power amplifier when the transmitting device is operated in the first operation mode; and
enabling the second power amplifier and disabling the first power amplifier when the transmitting device is operated in the second operation mode.

17. The transmitting method of claim 14, wherein the step of adjusting the output impedance of the configurable power amplifier device comprises:
using an impedance transformation network (ITN) to adjust the output impedance of the configurable power amplifier device employing the second power amplifier configuration when the transmitting device is operated in the second operation mode.

18. The transmitting method of claim 17, wherein the ITN is tunable.

19. The transmitting method of claim 14, wherein the first power amplifier configuration and the second power amplifier configuration have different power consumptions.

20. The transmitting method of claim 14, wherein a power consumption of the first power amplifier configuration is higher than a power consumption of the second power amplifier configuration.

21. The transmitting method of claim 20, wherein the adjusted output impedance generated by adjusting the output impedance of the configurable power amplifier device employing the second power amplifier configuration when the transmitting device is operated in the second operation mode is larger than an output impedance of the configurable power amplifier device employing the first power amplifier configuration when the transmitting device is operated in the first operation mode.

22. The transmitting method of claim 14, wherein when the RF signal complies with a first communications standard, the transmitting device is operated in the first operation mode; and when the RF signal complies with a second communications standard, the transmitting device is operated in the second operation mode.

23. The transmitting method of claim 22, wherein the first communications standard is a Wireless Fidelity (WiFi) protocol, and the second communications standard is a Bluetooth (BT) protocol.
